(19) United States
(12) Patent Application Publication
(10) Pub. No.: US 2002/0072156 A1
(43) Pub. Date: Jun. 13, 2002

(54) Method of forming gate electrode in semiconductor devices

(75) Inventors: Seung Chul Lee, Kyungki-Do (KR); Dong Jin Kim, Kyungki-Do (KR)

Correspondence Address: MORGAN LEWIS & BOCKIUS LLP, 1111 PENNSYLVANIA AVENUE NW, WASHINGTON, DC, 20004, US

(73) Assignee: Hynix Semiconductor Inc.

(21) Appl. No.: 09/998,313

(22) Filed: Dec. 3, 2001

(30) Foreign Application Priority Data
Dec. 8, 2000 (KR) 00-74644

(51) Int. Cl. H01L 21/00; H01L 21/84; H01L 21/337; H01L 21/8238

(52) U.S. Cl. 438/151; 438/186; 438/199

(57) ABSTRACT

The present invention relates a method of forming a gate electrode in semiconductor devices by which given regions of the hard mask layer, the tungsten film and the tungsten nitride film, and a given thickness of the polysilicon film are etched to form the spacer at the sidewall of the first pattern, a spacer is formed at the sidewall of the first pattern and the remaining polysilicon film and gate oxide film are etched using the first pattern at the sidewall of which the spacer is formed as a mask to form a dual gate electrode. Therefore. the present invention can prevent oxidization of a tungsten film without implementing a selective oxidization process. Further, the present invention can prevent intrusion of boron ions implanted into a polysilicon film into a gate oxide film by not performing the selective oxidization process.

### BACKGROUND OF THE INVENTION

1. Field of the Invention

The invention relates generally to a method of forming a gate electrode in a semiconductor device. More particularly, the invention relates to a method of forming a gate electrode in a semiconductor device capable of preventing oxidization of a tungsten film with no selective oxidization process and preventing intrusion of boron ions implanted into a polysilicon film into a gate oxide film without selective oxidization process, in a way that given regions of a hard mask layer, a tungsten film and a tungsten nitride film and a given thickness of a polysilicon film are etched to form a first pattern, a spacer is formed at the sidewall of the first pattern, and remaining polysilicon film and the gate oxide film are etched using the spacer as a mask to form a gate electrode, in order to form a surface channel dual gate electrode.

2. Description of the Prior Art

In order to develop higher integrated and higher speed semiconductor devices, it is required that Rs of a word line be reduced. Due to this, a gate electrode in a conventional tungsten polycide structure has been changed to a tungsten gate electrode. Along with this, as the operating voltage and the design rule are reduced, it has been impossible to secure a punch margin with a conventional buried channel transistor. Therefore, in order to improve this, there is a need for a surface channel transistor. However, when a tungsten gate electrode is formed, it is necessarily required that after a word line is defined, a selective oxidation process performed under a high temperature hydrogen atmosphere be performed. The selective oxidization process is necessary to compensate for etch damage and mitigate damages by ion implantation performed in a subsequent process. However, boron ions implanted to form a surface channel during the selective oxidization process are intruded into below the gate oxide film. Thus, a threshold voltage of the device is varied a flat band voltage is moved to make a smooth operation of a transistor difficult. Therefore, in devices using a tungsten gate electrode, there is no any technology of manufacturing a commercialized surface channel transistor even there is a need for a surface channel transistor.

### SUMMARY OF THE INVENTION

It is therefore an object of the present invention to provide a method of forming a gate electrode in a semiconductor device capable of forming a surface channel type transistor while obviating a selective oxidization process causing excessive thermal budget.

Another object of the present invention is to provide a method of forming a gate electrode in a semiconductor device capable of preventing oxidization of a tungsten film constituting a gate electrode without a selective oxidization process.

In order to accomplish the above object, a method of forming a gate electrode in a semiconductor device according to the present invention, is characterized in that it comprises the steps of forming a gate oxide film and a polysilicon film on a semiconductor substrate and then implementing impurity ion implantation process for the polysilicon film; sequentially forming a tungsten nitride film, a tungsten film and a hard mask layer on the entire structure; etching given regions of the hard mask layer, the tungsten film and the tungsten nitride film and a given thickness of the polysilicon film to form a first pattern; forming a spacer at the sidewall of the first pattern; and etching the remaining polysilicon film and gate oxide film using the first pattern at the sidewall of which the spacer is formed as a mask to form a dual gate electrode.

### BRIEF DESCRIPTION OF THE DRAWINGS

The aforementioned aspects and other features of the present invention will be explained in the following description, taken in conjunction with the accompanying drawings, wherein:

FIGS. 1A through 1C are cross-sectional views of a semiconductor device sequentially shown to explain a method of forming a gate electrode in the device according to the present invention.

### DETAILED DESCRIPTION OF PREFERRED EMBODIMENTS

The present invention will be described in detail by way of a preferred embodiment with reference to accompanying drawings, in which like reference numerals are used to identify the same or similar parts.

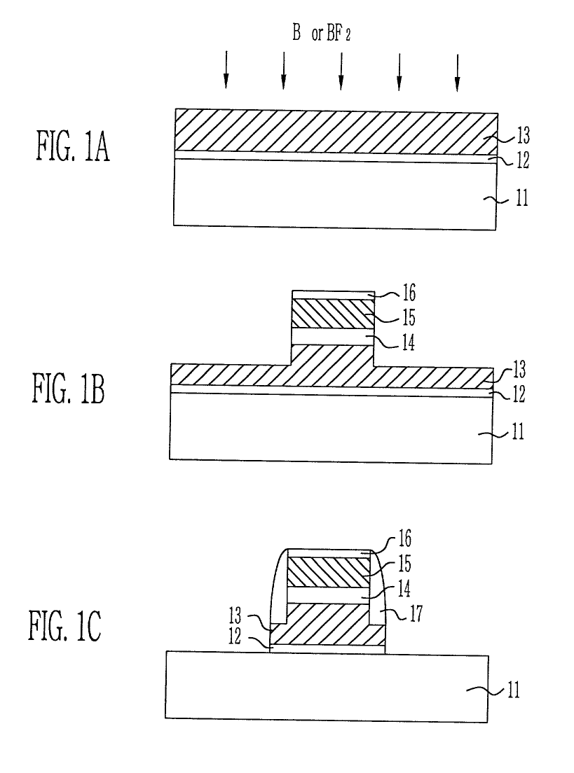

FIGS. 1A through 1C are cross-sectional views of a semiconductor device sequentially shown to explain a method of forming a gate electrode in the device according to the present invention.

Referring now to FIG. 1A, a gate oxide film 12 and a polysilicon film 13 are formed on a semiconductor substrate 11. Then, the polysilicon film 13 is experienced by an impurity ion implantation process. At this time, the gate oxide film 11 is formed in thickness of 30˜100 Å, and the polysilicon film 13 is formed in thickness of 500˜2000 Å at the temperature of 510˜650° C. Further, impurity ions implanted into the polysilicon film 13 may include one of boron (B), BF₂ and a mixture ion of B and BF₂. At this time, in case of implanting B ions, the amount of 2E15˜5E15 cm⁻² is implanted with the energy of 2˜30 keV. On the other hand, in case of implanting BF₂ ions, the amount of 2E15˜7E15 cm⁻² is implanted with the energy of 5˜50 keV.

By reference to FIG. 1B, a tungsten nitride film (WNₓ) 14, a tungsten film 15 and a hard mask layer 16 are sequentially formed on the entire structure. At this time, the tungsten nitride film 14 is formed in thickness of 20˜200 Å and the tungsten film 15 is formed in thickness of 200˜1000 Å. Meanwhile, the hard mask layer 16 is formed to prevent damage of the tungsten film 15 in a subsequent spacer etching process, which is for example formed of a nitride film. Also, given regions of the hard mask layer 16, the tungsten film 15 and the tungsten nitride film 14 are etched and a given thickness of the polysilicon film 14 is also etched to form a first pattern. Etching process for forming the first pattern is implemented at the pressure of 10˜30 mTorr using Cl₂ gas of 10˜150 sccm and SF₆ of 10˜100 sccm. At this time, the polysilicon film 13 is etched in 300˜600 Å.

Referring now to FIG. 1C, a spacer 17 is formed at the sidewall of the first pattern. The spacer 17 is formed by forming a single layer of a nitride film or an oxide film, a dual layer of a nitride film and an oxide film or a dual layer of the oxide film and the nitride on the entire structure in thickness of 200˜500 Å and then implementing a blanket etching process. Etching process for forming the spacer 17 is implemented at the temperature of 600˜800° C. at the pressure of over 1000 mTorr using CHF₃ gas of 10˜30 sccm and CF₄ gas of 10˜30 sccm. Also, the remaining polysilicon film 13 and the gate oxide film 12 are etched using the first pattern at the sidewall of which the spacer 17 is formed, thus forming a dual gate electrode.

As can be understood from the above description, the present invention etches given regions of the hard mask layer, the tungsten film and the tungsten nitride film, and a given thickness of the polysilicon film to form the spacer at the sidewall of the first pattern, and etches the remaining polysilicon film and the gate oxide film using the first pattern at the sidewall of which the spacer is formed as a mask to form a gate electrode. Therefore, the present invention can prevent oxidization of a tungsten film without implementing a selective oxidization process. Further, the present invention can prevent intrusion of boron ions implanted into a polysilicon film into a gate oxide film by not performing the selective oxidization process.

The present invention has been described with reference to a particular embodiment in connection with a particular application. Those having ordinary skill in the art and access to the teachings of the present invention will recognize additional modifications and applications within the scope thereof.

It is therefore intended by the appended claims to cover any and all such applications, modifications, and embodiments within the scope of the present invention.

What is claimed are:

1. A method of forming a gate electrode in semiconductor devices, comprising the steps of:
forming a gate oxide film and a polysilicon film on a semiconductor substrate and then implementing impurity ion implantation process for said polysilicon film;
sequentially forming a tungsten nitride film, a tungsten film and a hard mask layer on the entire structure;
etching given regions of said hard mask layer, said tungsten film and said tungsten nitride film and a given thickness of said polysilicon film to form a first pattern;
forming a spacer at the sidewall of said first pattern; and
etching the remaining polysilicon film and gate oxide film using said first pattern at the sidewall of which said spacer is formed as a mask to form a dual gate electrode.

2. The method of forming a gate electrode in semiconductor devices according to claim 1, wherein said gate oxide film is formed in thickness of 30˜100 Å.

3. The method of forming a gate electrode in semiconductor devices according to claim 1, wherein said polysilicon film is formed in thickness of 500˜2000 Å at the temperature of 510-650° C.

4. The method of forming a gate electrode in semiconductor devices according to claim 1, wherein said impurity ions is one of boron, BF₂ and a mixture ion of boron and BF₂.

5. The method of forming a gate electrode in semiconductor devices according to claim 4, wherein said B ions are implanted with the amount of 2E15˜5E15 cm⁻² and the energy of 2˜30 keV.

6. The method of forming a gate electrode in semiconductor devices according to claim 4, wherein said BF₂ ions are implanted with the amount of 2E15˜7E15 cm⁻² and the energy of 5˜50 keV.

7. The method of forming a gate electrode in semiconductor devices according to claim 1. wherein said tungsten nitride film is formed in thickness of 20˜200 Å.

8. The method of forming a gate electrode in semiconductor devices according to claim 1, wherein said tungsten film is formed in thickness of 200˜1000 Å.

9. The method of forming a gate electrode in semiconductor devices according to claim 1, wherein said hard mask layer is formed of a nitride film.

10. The method of forming a gate electrode in semiconductor devices according to claim 1, wherein an etching process for forming said first pattern is implemented at the pressure of 10˜30 mTorr using Cl₂ gas of 10˜150 sccm and SF₆ of 10˜100 sccm.

11. The method of forming a gate electrode in semiconductor devices according to claim 1, wherein said first pattern is formed by etching said polysilicon film in thickness of 300˜600 Å.

12. The method of forming a gate electrode in semiconductor devices according to claim 1, wherein said spacer is formed by forming a single layer of a nitride film or an oxide film, a dual layer of a nitride film and an oxide film or a dual layer of the oxide film and the nitride in thickness of 200˜500 Å and then performing a blanket etching process.

13. The method of forming a gate electrode in semiconductor devices according to claim 1, wherein the spacer is formed by an etching process performed at the temperature of 600˜800° C. at the pressure of over 1000 mTorr using CHF₃ gas of 10˜30 sccm and CF₄ gas of 10˜30 sccm.
